(19) United States
(12) Patent Application Publication
(10) Pub. No.: US 2021/0036203 A1
(43) Pub. Date: Feb. 4, 2021

(54) THERMOELECTRIC CONVERSION ELEMENT LAYER AND METHOD FOR PRODUCING SAME

(71) Applicant: LINTEC CORPORATION, Itabashi-ku (JP)

(72) Inventors: Wataru MORITA, Saitama-shi (JP); Kunihisa KATO, Warabi-shi (JP); Tsuyoshi MUTO, Saitama-shi (JP)

(73) Assignee: LINTEC CORPORATION, Itabashi-ku (JP)

(21) Appl. No.: 16/498,309

(22) PCT Filed: Mar. 29, 2018
(86) PCT No.: PCT/JP2018/013111

§ 371 Date: Sep. 26, 2019

(30) Foreign Application Priority Data
Mar. 30, 2017 (JP) 2017-068806

(51) Int. Cl. H01L 35/32; H01L 35/02

(52) U.S. Cl. CPC H01L 35/32; H01L 35/02

(57) ABSTRACT

The present invention provides a thermoelectric conversion device layer having excellent durability and a method of producing the same. Specifically, the present invention provides a thermoelectric conversion device layer including a thermoelectric conversion module including, on one face of a film substrate, a thermoelectric element layer in which a P-type thermoelectric element layer and an N-type thermoelectric element layer are alternately arranged to be adjacent to each other in the in-plane direction and disposed in series; and further a sealing layer on the face side of the thermoelectric element layer, wherein the sealing layer has a water vapor transmission rate at 40° C. and 90% RH, as prescribed in JIS K7129:2008, of 1,000 g·m⁻²·day⁻¹ or less; and a method of producing the same.

### TECHNICAL FIELD

The present invention relates to a thermoelectric conversion device layer and a method of producing the same.

### BACKGROUND ART

As an energy conversion technology utilizing thermoelectric conversion, a thermoelectric power generation technology and a Peltier cooling technology have been known. The thermoelectric power generation technology is a technology that utilizes conversion from thermal energy to electric energy through the Seebeck effect, and the technology is attracting increasing attention particularly as an energy saving technology capable of recovering, as electric energy, unused waste heat energy formed from the fossil fuel resources or the like used in buildings, factories, and the like. The Peltier cooling technology is a technology that utilizes conversion from electric energy to thermal energy through the Peltier effect in contrast to the thermoelectric power generation, and the technology is being used in a wine refrigerator, a small portable refrigerator, cooling for a CPU used in a computer or the like, and a component or device that requires precise temperature control, such as temperature control of a semiconductor laser oscillator for optical communication.

In a thermoelectric conversion device utilizing such thermoelectric conversion, there is involved such a problem that the thermoelectric performance of a thermoelectric element layer is lowered, and the resistance of metal electrodes increases, so that thermoelectric conversion module does not withstand long-term use depending upon the environmental condition of an installation side, such as a high-temperature and high-humidity condition.

PTL 1 discloses a thermoelectric conversion device in which a film-like substrate constituted of two or more kinds of materials having a different thermal conductivity from each other and having flexibility is provided on the both faces of a thermoelectric conversion module which is configured of a P-type thermoelectric element of a thin film composed of a P-type material and an N-type thermoelectric element of a thin film composed of an N-type material, and a material having a high thermal conductivity is configured such that it is located in a part of the outer face of the substrate. In addition, PTL 2 discloses a configuration of a thermoelectric conversion apparatus in which a frame composed of at least one synthetic resin among polyphenylene sulfide, polybutylene terephthalate, and polypropylene is used.

### CITATION LIST

### Patent Literature

PTL 1: JP 2006-186255 A

PTL 2: JP 10-12934 A

### Technical Problem

However, in the first place, PTL 1 merely discloses the configuration in which a temperature difference is efficiently given between electrodes or connection parts of the thermoelectric element, and the thermoelectric conversion device disclosed in PTL 1 has the configuration in which the film-like substrate having flexibility comes into direct contact with the thermoelectric element. However, PTL 1 neither describes nor suggests the use for the thermoelectric element as a sealing layer and does not make any investigations regarding durability, etc. as the thermoelectric conversion device.

In PTL 2, with respect to the frame, it is described in paragraph 0032 that if frames having a high water vapor transmission rate were used, dew would be formed on electrode surfaces or the like especially on the heat-absorbing side (low-temperature side), causing short circuiting, electrode corrosion, increased thermal resistance, or the like, and hence, one having a low water vapor transmission rate is chosen. However, the foregoing frame does not come into direct contact with the thermoelectric conversion device (thermoelectric element layer) and is one in which it is not disposed on the top and bottom faces thereof, and therefore, the water vapor in the air, which comes into direct contact with the thermoelectric element layer of the thermoelectric conversion module, cannot be suppressed. Furthermore, similar to PTL 1, PTL 2 does not make any investigations regarding durability, etc. as the thermoelectric conversion device.

In view of the aforementioned problem, a problem of the present invention is to provide a thermoelectric conversion device layer having excellent durability and a method of producing the same.

### Solution to Problem

In order to solve the aforementioned problem, the present inventors made extensive and intensive investigations. As a result, it has been found that the aforementioned problem is solved by laminating a sealing layer having a specified water vapor transmission rate on the face of a thermoelectric element layer of a thermoelectric conversion module having at least a thermoelectric element layer on a film substrate, thereby leading to accomplishment of the present invention.

Specifically, the present invention provides the following (1) to (11).
(1) A thermoelectric conversion device layer including a thermoelectric conversion module including, on one face of a film substrate, at least a thermoelectric element layer in which a P-type thermoelectric element layer and an N-type thermoelectric element layer are alternately arranged to be adjacent to each other in the in-plane direction and disposed in series; and further a sealing layer on the face side of the thermoelectric element layer, wherein the sealing layer has a water vapor transmission rate at 40° C. and 90% RH, as prescribed in JIS K7129:2008, of 1,000 g·m⁻²·day⁻¹ or less.
(2) The thermoelectric conversion device layer as set forth in the above (1), further including, on the face of the sealing layer, a sealing base material layer having a water vapor transmission rate at 40° C. and 90% RH, as prescribed in JIS K7129:2008, of 10 g·m⁻²·day⁻¹ or less.
(3) The thermoelectric conversion device layer as set forth in the above (1) or (2), further including, on the other face of the film substrate, the sealing layer, or the sealing layer and the sealing base material layer in this order.
(4) The thermoelectric conversion device layer as set forth in any of the above (1) to (3), wherein a main component constituting the sealing layer is a polyolefin-based resin, a curable resin, or an acrylic resin.
(5) The thermoelectric conversion device layer as set forth in any of the above (1) to (4), wherein the sealing layer has a thickness of 0.5 to 100 μm.
(6) The thermoelectric conversion device layer as set forth in the above (2) or (3), wherein the sealing base material layer is an inorganic layer or a layer containing a polymer compound.
(7) The thermoelectric conversion device layer as set forth in any of the above (2), (3), and (6), wherein the sealing base material layer has a thickness of 10 to 100 μm.
(8) The thermoelectric conversion device layer as set forth in any of the above (1) to (7), wherein the thermoelectric element layer and the sealing layer come into direct contact with each other.
(9) The thermoelectric conversion device layer as set forth in any of the above (1) to (8), wherein the sealing layer is composed of a sealant having pressure sensitive adhesiveness.
(10) A method of producing a thermoelectric conversion device layer which is the thermoelectric conversion device layer as set forth in any of the above (1) to (9), the method including a step of forming the thermoelectric element layer on one face of the film substrate; and a step of forming the sealing layer on the face of the thermoelectric element layer.
(11) A thermoelectric conversion device layer including a thermoelectric conversion module including, on one face of a film substrate, at least a thermoelectric element layer in which a P-type thermoelectric element layer and an N-type thermoelectric element layer are alternately arranged to be adjacent to each other in the in-plane direction and disposed in series; and further a sealing layer on the face side of the thermoelectric element layer, wherein the sealing layer is composed of a curable resin.

### Advantageous Effects of Invention

In accordance with the present invention, it is possible to provide a thermoelectric conversion device layer having excellent durability and a method of producing the same.

### BRIEF DESCRIPTION OF DRAWINGS

FIG. 1 is a cross-sectional view showing a first embodiment of a thermoelectric conversion device layer of the present invention.

FIG. 2 is a cross-sectional view showing a second embodiment of a thermoelectric conversion device layer of the present invention.

FIG. 3 is a plan view showing a configuration of a thermoelectric conversion module used in the Examples of the present invention.

### DESCRIPTION OF EMBODIMENTS s

### [Thermoelectric Conversion Device Layer]

The thermoelectric conversion device layer of the present invention is a thermoelectric conversion device layer including a thermoelectric conversion module including, on one face of a film substrate, at least a thermoelectric element layer in which a P-type thermoelectric element layer and an N-type thermoelectric element layer are alternately arranged to be adjacent to each other in the in-plane direction and disposed in series; and further a sealing layer on the face side of the thermoelectric element layer, wherein the sealing layer has a water vapor transmission rate at 40° C. and 90% RH, as prescribed in JIS K7129:2008, of 1,000 g·m⁻²·day⁻¹ or less.

The thermoelectric conversion device layer of the present invention is described by reference to the accompanying drawings.

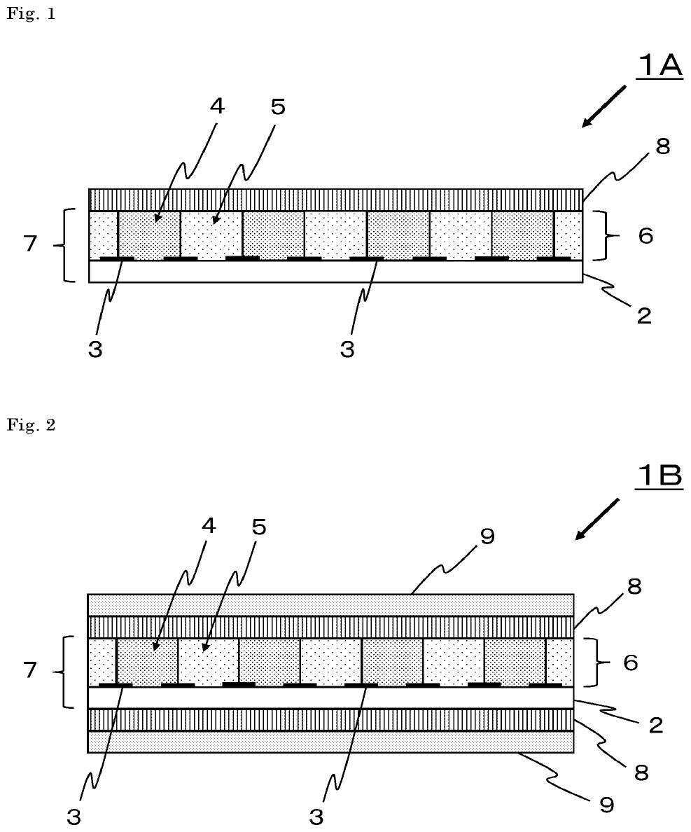

FIG. 1 is a cross-sectional view showing a first embodiment of a thermoelectric conversion device layer of the present invention. A thermoelectric conversion device layer 1A is configured of a thermoelectric conversion module 7 including a thermoelectric element layer 6 composed of P-type thermoelectric element layers 5 and N-type thermoelectric element layers 4 and formed on one face of a film substrate 2 having electrodes 3; and a sealing layer 8 laminated on the face on the side of the thermoelectric element layer 6 of the both faces of the thermoelectric conversion module 7.

Similarly, FIG. 2 is a cross-sectional view showing a second embodiment of a thermoelectric conversion device layer of the present invention. A thermoelectric conversion device layer 1B is configured of a thermoelectric conversion module 7 including a thermoelectric element layer 6 composed of P-type thermoelectric element layers 5 and N-type thermoelectric element layers 4 and formed on one face of a film substrate 2 having electrodes 3; a sealing layer 8 laminated on the both faces of the thermoelectric conversion module 7; and further a sealing base material layer 9 laminated on the face of each of the sealing layers 8.

### <Sealing Layer>

The thermoelectric conversion device layer of the present invention includes a sealing layer. The water vapor transmission rate of the sealing layer at 40° C. and 90% RH as prescribed in JIS K7129:2008 is 1,000 g·m⁻²·day⁻¹ or less. When the water vapor transmission rate is more than 1,000 g·m⁻²·day⁻¹, in view of the fact that the water vapor in the air or the like is liable to transmit through the sealing layer, a thermoelectric semiconductor material which is used for the thermoelectric element layer is degraded due to corrosion or the like, and as a result, an electric resistance value of the thermoelectric element layer increases, and a thermoelectric performance is lowered. The water vapor transmission rate is preferably 700 g·m⁻²·day⁻¹ or less, more preferably 200 g·m⁻²·day⁻¹ or less, still more preferably 50 g·m⁻²·day⁻¹ or less, and especially preferably 10 g·m⁻²·day⁻¹ or less. When the water vapor transmission rate falls within this range, interpenetration of the water vapor into the thermoelectric element layer is suppressed, and degradation of the thermoelectric element layer to be caused due to corrosion or the like is suppressed. For this reason, an increase of the electric resistance value of the thermoelectric element layer is small, and it becomes possible to use the thermoelectric conversion device layer for a long period of time in a state that the initial thermoelectric performance is maintained.

Though the disposition of the sealing layer which is used in the present invention on the face of the thermoelectric element layer of the thermoelectric conversion module is not particularly limited, it is necessary to properly regulate the disposition by the disposition of the thermoelectric element layer of the thermoelectric conversion module to be used, namely the P-type thermoelectric element layer and the N-type thermoelectric element layer. It is preferred to dispose the sealing layer so as to come into direct contact with the face of the thermoelectric element layer, and it is preferred to dispose the sealing layer so as to cover the whole of the thermoelectric element layer. When the sealing layer is disposed on the thermoelectric element layer of the thermoelectric conversion module in the aforementioned manner, the transmission of the water vapor in the air can be effectively suppressed, and the performance of the thermoelectric conversion device layer can be maintained over a long period of time. Furthermore, it is preferred that the sealing layer is disposed on the both faces of the thermoelectric conversion module. According to this, the transmission of the water vapor in the air can be more effectively suppressed.

Preferably, a main component constituting the sealing layer which is used in the present invention is a polyolefin-based resin, a curable resin, or an acrylic resin.

Preferably, the sealing layer is composed of a sealant having pressure sensitive adhesiveness (hereinafter sometimes referred to as “sealant composition”). In this specification, it is meant by the terms “having pressure sensitive adhesiveness” that the sealant has tackiness, adhesiveness, or pressure-sensitive tackiness such that adhesion can be achieved by being sensitive to pressure at the initial stage of sticking. By using the sealing layer, lamination on the thermoelectric conversion module can be easily achieved, and it also becomes easy to stick to the thermoelectric conversion module, the sealing base material layer, or the like.

Preferably, the sealing layer is composed of a curable resin. When the sealing layer is composed of a curable resin, the surface of the sealing layer becomes tack-free, and handling properties are improved.

Though the polyolefin-based resin is not particularly limited, examples thereof include a diene-based rubber having a carboxylic acid-based functional group (hereinafter sometimes referred to as “diene-based rubber”) and a rubber-based polymer not having a carboxylic acid-based functional group hereinafter sometimes referred to as “rubber-based polymer”).

The diene-based rubber is a diene-based rubber constituted of a polymer having a carboxylic acid-based functional group at the terminal of the main chain and/or in the side chain. Here, the “carboxylic acid-based functional group” refers to “a carboxy group or a carboxylic anhydride group”. In addition, the “diene-based rubber” refers to “a rubber-like polymer having a double bond in the polymer main chain”.

The diene-based rubber is not particularly limited so long as it is a diene-based rubber having a carboxylic acid-based functional group.

Examples of the diene-based rubber include a carboxylic acid-based functional group-containing polybutadiene-based rubber, a carboxylic acid-based functional group-containing polyisoprene-based rubber, a copolymer rubber of butadiene and isoprene containing a carboxylic acid-based functional group, and a copolymer rubber of butadiene and n-butene containing a carboxylic acid-based functional group. Of these, a carboxylic acid-based functional group-containing polyisoprene-based rubber is preferred as the diene-based rubber from the viewpoint that a sealing layer having sufficiently high cohesive strength after crosslinking may be efficiently formed.

The diene-based rubber can be used either alone or in combination of two or more thereof.

The diene-based rubber can be, for example, obtained by a method of performing a copolymerization reaction using a monomer having a carboxy group; and a method of adding maleic anhydride to a polymer, such as polybutadiene, as described in JP 2009-29976 A.

The blending amount of the diene-based rubber is preferably 0.5 to 95.5% by mass, more preferably 1.0 to 50% by mass, and still more preferably 2.0 to 20% by mass in the sealant composition. When the blending amount of the diene-based rubber is 0.5% by mass or more in the sealant composition, the sealing layer having sufficient cohesive strength can be efficiently formed. In addition, by not excessively increasing the blending amount of the diene-based rubber, the sealing layer having sufficient pressure sensitive adhesive strength can be efficiently formed.

A crosslinking agent which is used in the present invention is a compound capable of reacting with the carboxylic acid-based functional group of the diene-based rubber, to form a crosslinked structure.

Examples of the crosslinking agent include an isocyanate-based crosslinking agent, an epoxy-based crosslinking agent, an aziridine-based crosslinking agent, and a metal chelate-based crosslinking agent.

The rubber-based polymer refers to a “resin exhibiting rubber elasticity at 25° C”. Preferably, the rubber-based polymer is a rubber having a polymethylene type saturated main chain or a rubber having an unsaturated carbon bond in the main chain.

Specifically, examples of such a rubber-based polymer include a homopolymer of isobutylene (polyisobutylene, IM), a copolymer of isobutylene and n-butene, a natural rubber (NR), a homopolymer of butadiene (butadiene rubber, BR), a homopolymer of chloroprene (chloroprene rubber, CR), a homopolymer of isoprene (isoprene rubber, IR), a copolymer of isobutylene and butadiene, a copolymer of isobutylene and isoprene (butyl rubber, IIR), a halogenated butyl rubber, a copolymer of styrene and 1,3-butadiene (styrene-butadiene rubber, SBR), a copolymer of acrylonitrile and 1,3-butadiene (nitrile rubber), a styrene-1,3-butadiene-styrene block copolymer (SBS), a styrene-isoprene-styrene block copolymer (SIS), and an ethylene-propylene-non-conjugated diene ternary copolymer. Of these, an isobutylene-based polymer, such as a homopolymer of isobutylene, a copolymer of isobutylene and n-butene, a copolymer of isobutylene and butadiene, and a copolymer of isobutylene and isoprene, is preferred, and a copolymer of isobutylene and isoprene is more preferred from the viewpoint that not only it itself has an excellent water barrier capability, but also it is readily mixed with the diene-based rubber (A)—is easy to form a uniform sealing layer.

In the case of blending the rubber-based polymer, its blending amount is preferably 0.1% by mass to 99.5% by mass, more preferably 10 to 99.5% by mass, still more preferably 50 to 99.0% by mass, and especially preferably 80 to 98.0% by mass in the sealant composition.

Examples of the curable resin include an epoxy-based resin, a silicone-based resin, a phenol-based resin, a melamine-based resin, and a urea-based resin. From the viewpoint of excellent heat resistance, workability, and reliability, an epoxy-based resin is preferably used. The curable resin can be cured by heat or energy rays.

Though the epoxy-based resin is not particularly limited, it is preferably a polyfunctional epoxy compound having at least two epoxy groups in a molecule thereof.

Examples of the epoxy compound having at least two epoxy groups include bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, a novolak type epoxy resin (for example, a phenol-novolak type epoxy resin, a cresol-novolak type epoxy resin, and a brominated phenol-novolak type epoxy resin), hydrogenated bisphenol A diglycidyl ether, hydrogenated bisphenol F diglycidyl ether, hydrogenated bisphenol S diglycidyl ether, pentaerythritol polyglycidyl ether, 1,6-hexanecliol diglycidyl ether, diglycidyl hexahydrophthalate, neopentyl glycol diglycidyl ether, trimethylolpropane polyglycidyl ether, 2,2-bis (3-glycidyl-4-glycidyloxyphenyl)prop ane, and dimethylol tricyclodecane diglycidyl ether.

These polyfunctional epoxy compounds can be used either alone or in combination of two or more thereof.

A lower limit of the molecular weight of the polyfunctional epoxy compound is preferably 700 or more, and more preferably 1,200 or more. An upper limit of the molecular weight of the polyfunctional epoxy compound is preferably 5,000 or less, and more preferably 4,500 or less.

The epoxy equivalent of the polyfunctional epoxy compound is preferably 100 g/eq or more and 500 g/eq or less, and more preferably 150 g/eq or more and 300 g/eq or less.

The content of the epoxy-based resin in the sealant composition is preferably 10 to 50% by mass, and more preferably 10 to 40% by mass.

Though the acrylic resin is not particularly limited, a (meth)acrylic acid ester-based copolymer is preferred.

As this (meth)acrylic acid ester-based copolymer, copolymers of an alkyl (meth)acrylate in which the alkyl group of the ester moiety has 1 to 18 carbon atoms and a crosslinkable functional group-containing ethylenic monomer or other monomer, which is used as the need arises, can be preferably exemplified. Examples of the alkyl (meth)acrylate in which the alkyl group of the ester moiety has 1 to 18 carbon atoms include methyl acrylate, methyl methacrylate, ethyl acrylate, ethyl methacrylate, propyl acrylate, propyl methacrylate, isopropyl acrylate, isopropyl methacrylate, n-butyl acrylate, n-butyl methacrylate, isobutyl acrylate, isobutyl methacrylate, n-hexyl acrylate, n-hexyl methacrylate, 2-ethylhexyl acrylate, 2-ethylhexyl methacrylate, lauryl acrylate, lauryl methacrylate, stearyl acrylate, and stearyl methacrylate. These may be used alone or may be used in combination of two or more thereof.

The crosslinkable functional group-containing ethylenic monomer which is used as the need arises is an ethylenic monomer having a functional group, such as a hydroxy group, a carboxy group, an amino group, a substituted amino group, and an epoxy group, in a molecule thereof, and preferably, a hydroxy group-containing ethylenically unsaturated compound or a carboxy group-containing ethylenically unsaturated compound is used. Specific examples of such a crosslinkable functional group-containing ethylenic monomer include hydroxy group-containing (meth)acrylates, such as 2-hydroxyethyl acrylate, 2-hydroxyethyl methacrylate, 2-hydroxypropyl acrylate, 2-hydroxypropyl methacrylate, 2-hydroxybutyl acrylate, 2-hydroxybutyl methacrylate, 4-hydroxybutyl acrylate, and 4-hydroxybutyl methacrylate; and carboxy group-containing ethylenically unsaturated compounds, such as acrylic acid, methacrylic acid, crotonic acid, maleic acid, itaconic acid, and citraconic acid. The aforementioned crosslinkable functional group-containing ethylenic monomers may be used either alone or in combination of two or more thereof.

Examples of the other monomer which is used as the need arises include (meth)acrylic acid esters having an alicyclic structure, such as cyclohexyl acrylate and isobornyl acrylate; vinyl esters, such as vinyl acetate and vinyl propionate; olefins, such as ethylene, propylene, and isobutylene; halogenated olefins, such as vinyl chloride and vinylidene chloride; styrene-based monomers, such as styrene and α-methylstyrene; diene-based monomers, such as butadiene, isoprene, and chloroprene; nitrile-based monomers, such as acrylonitrile and methacrylonitrile; and N,N-dialkyl-substituted acrylamides, such as N,N-dimethylacrylamide and N,N-dimethylmethacrylamide. These may be used alone or may be used in combination of two or more thereof.

The foregoing (meth)acrylic acid ester and crosslinkable functional group-containing ethylenic monomer or other monomer, which is used as the need arises, are used in predetermined ratios, respectively and copolymerized with each other by adopting a conventionally known method, thereby producing a (meth)acrylic acid ester-based polymer having a weight average molecular weight of preferably about 300,000 to 1,500,000, and more preferably about 350,000 to 1,300,000.

The aforementioned weight average molecular weight is a value measured by the gel permeation chromatography (GPC) as expressed in terms of standard polystyrene.

As the crosslinking agent which is used as the need arises, an arbitrary material can be properly selected and used among those which are customarily used as a crosslinking agent in conventional acrylic resins. Examples of such a crosslinking agent include a polyisocyanate compound, an epoxy compound, a melamine resin, a urea resin, a dialdehyde, a methylol polymer, an aziridine-based compound, a metal chelate compound, a metal alkoxide, and a metal salt. In the case where the aforementioned (meth)acrylic acid ester-based copolymer has a hydroxy group as the crosslinkable functional group, a polyisocyanate compound is preferred, whereas in the case where the (meth)acrylic acid ester-based copolymer has a carboxy group, a metal chelate compound or an epoxy compound is preferred.

The content of the acrylic resin in the sealant composition is preferably 30 to 95% by mass, and more preferably 40 to 90% by mass.

In the sealant constituting the sealing layer, other component may be contained within a range where the effects of the present invention are not impaired. Examples of the other component which may be contained in the sealant include a high thermal conductive material, a flame retardant, a tackifier, a UV absorber, an antioxidant, an antiseptic, an antifungal agent, a plasticizer, an anti-foaming agent, and a wettability controlling agent.

The sealing layer may be either a single layer or a laminate of two or more layers so long as it is satisfied with the aforementioned water vapor transmission rate. In the case of a laminate of two or more layers, those layers may be the same as or different from each other.

The thickness of the sealing layer is preferably 0.5 to 100 μm, more preferably 3 to 50 μm, and still more preferably 5 to 30 μm. When the thickness of the sealing layer falls within this range, in the case where the sealing layer is laminated on the face of the thermoelectric element layer of the thermoelectric conversion module, a water vapor transmission rate can be suppressed, and the durability of the thermoelectric conversion device layer is improved.

Furthermore, as mentioned above, it is preferred that the thermoelectric element layer comes into direct contact with the sealing layer. When the thermoelectric element layer comes into direct contact with the sealing layer, the water vapor in the air does not exist directly between the thermoelectric element layer and the sealing layer, and therefore, the interpenetration of the thermoelectric element layer into the water vapor is suppressed, and the sealing properties of the sealing layer are improved.

### <Sealing Base Material Layer>

Preferably, the thermoelectric conversion device layer of the present invention further includes a sealing base material layer. In order to further suppress the transmission of the water vapor in the air, it is preferred that the sealing base material layer is laminated on the aforementioned sealing layer.

The sealing base material layer which is used in the present invention is preferably used upon being laminated on any of the sealing layers of the thermoelectric conversion module, and it is more preferably used upon being laminated on the sealing layers of the both faces of the thermoelectric conversion module as shown in FIG. 2. According to this, interpenetration of the water vapor into the thermoelectric element layer can be more effectively suppressed.

From the viewpoint of suppressing the water vapor transmission rate in the air (hereinafter sometimes referred to as “gas barrier properties”), it is preferred that the sealing base material layer which is used in the present invention is composed of an inorganic layer or a layer containing a polymer compound (hereinafter sometimes referred to as “gas barrier layer”) on a base material.

As the base material, one having flexibility is used. Examples thereof include a polyimide, a polyamide, a polyamide-imide, a polyphenylene ether, a polyetherketone, a polyetheretherketone, a polyolefin, a polyester, a polycarbonate, a polysulfone, a polyether sulfone, a polyphenylene sulfide, a polyarylate, an acrylic resin, a cycloolefin-based polymer, and an aromatic polymer. Of these, examples of the polyester include polyethylene terephthalate (PET), polybutylene terephthalate, polyethylene naphthalate (PEN), and a polyarylate. In addition, examples of the cycloolefin-based polymer include a norbornene-based polymer, a monocyclic cycloolefin-based polymer, a cyclic conjugated diene-based polymer, a vinyl alicyclic hydrocarbon, and a hydrogenated product thereof. Of such base materials, biaxially oriented polyethylene terephthalate (PET) and polyethylene naphthalate (PEN) are especially preferred from the viewpoint of cost and heat resistance.

Examples of the inorganic layer include inorganic deposited films, such as deposited films of an inorganic compound or a metal.

Examples of a raw material of the deposited film of an inorganic compound include an inorganic oxide, such as silicon oxide, aluminum oxide, magnesium oxide, zinc oxide, indium oxide, and tin oxide; an inorganic nitride, such as silicon nitride, aluminum nitride, and titanium nitride; an inorganic carbide; an inorganic sulfide; an inorganic oxynitride, such as silicon oxynitride; an inorganic oxycarbide; an inorganic nitride carbide; and an inorganic oxynitride carbide.

Examples of a raw material of the deposited film of a metal include aluminum, magnesium, zinc, and tin. These can be used either alone or in combination of two or more thereof.

Of these, an inorganic deposited film formed of, as a raw material, an inorganic oxide, an inorganic nitride, or a metal is preferred from the viewpoint of gas barrier properties.

Examples of the polymer compound include a silicon-containing polymer compound, such as a polyorganosiloxane and a polysilazane-based compound, a polyimide, a polyamide, a polyamide-imide, a polyphenylene ether, a polyetherketone, a polyetheretherketone, a polyolefin, and a polyester. These polymer compounds can be used either alone or in combination of two or more thereof.

Of these, a silicon-containing polymer compound is preferred as the polymer compound having gas barrier properties. Examples of the silicon-containing polymer compound include a polysilazane-based compound, a polycarbosilane-based compound, a polysilane-based compound, and a polyorganosiloxane-based compound. Of these, a polysilazane-based compound is preferred from the viewpoint that the barrier layer having excellent gas barrier properties can be formed.

A deposited film formed of an inorganic compound, or a silicon oxynitride composed of a layer having, as main constituent atoms, oxygen, nitrogen, and silicon, which is formed by subjecting a layer containing a polysilazane-based compound to a modification treatment, is preferably used from the viewpoint that it has interlayer adhesion, gas barrier properties, and flexibility.

The gas barrier layer which is used for the sealing base material layer can be, for example, formed by subjecting a polysilazane compound-containing layer to a plasma ion injection treatment, a plasma treatment, a UV irradiation treatment, a heat treatment, or the like. Examples of the ion which is injected by the plasma ion injection treatment include hydrogen, nitrogen, oxygen, argon, helium, neon, xenon, and krypton.

Examples of a specific treatment method of the plasma ion injection treatment include a method in which ions existing in a plasma generated using an external electric field are injected into the polysilazane compound-containing layer; and a method in which ions existing in a plasma generated only by an electric field due to a negative high-voltage pulse to be impressed to a layer composed of a gas barrier layer-forming material without using an external electric field are injected into the polysilazane compound-containing layer.

The plasma treatment is a method in which a polysilazane compound-containing layer is exposed in a plasma, thereby modifying the layer containing the silicon-containing polymer. For example, the plasma treatment can be, for example, performed according to the method described in JP 2012-106421 A. The UV irradiation treatment is a method in which ultraviolet rays are irradiated on a polysilazane compound-containing layer, thereby modifying the layer containing the silicon-containing polymer. For example, the UV modification treatment can be performed according to the method described in JP 2013-226757 A.

Of these, the ion injection treatment is preferred in view of the fact that the modification can be efficiently achieved to the interior of the polysilazane compound-containing layer without roughening the surface thereof, whereby the gas barrier layer with more excellent gas barrier properties can be formed.

The thickness of the inorganic layer or the layer containing a polymer compound is preferably 0.03 to 1 μm, more preferably 0.05 to 0.8 μm, and still more preferably 0.10 to 0.6 μm. When the thickness of the inorganic layer or the layer containing a polymer compound falls within this range, the water vapor transmission rate can be effectively suppressed.

The water vapor transmission rate of the sealing base material layer at 40° C. and 90% RH as prescribed in JIS K7129:2008 is preferably 10 g·m⁻²·day⁻¹ or less, more preferably 5 g·m⁻²·day⁻¹ or less, and still more preferably 1 g·m⁻²·day⁻¹ or less. When the water vapor transmission rate falls within this range, transmission of the water vapor into the sealing layer and the thermoelectric element layer is suppressed, and degradation of the thermoelectric element layer to be caused due to corrosion or the like is suppressed. For this reason, an increase of the electric resistance value of the thermoelectric element layer becomes small, and it becomes possible to use the thermoelectric element layer for a long period of time in a state that the initial thermoelectric performance is maintained.

The thickness of the sealing base material layer having the inorganic layer or the layer containing a polymer compound is preferably 10 to 100 μm, more preferably 15 to 50 μm, and still more preferably 20 to 40 μm. When the thickness of the sealing base material layer falls within this range, not only excellent gas barrier properties are obtained, but also both the flexibility and the coating film strength can be made compatible with each other.

### <Thermoelectric Conversion Module>

The thermoelectric conversion module which is used in the present invention includes, on one face of a film substrate, a thermoelectric element layer in which a P-type thermoelectric element layer and an N-type thermoelectric element layer are disposed alternately to be adjacent to each other and electrically connected with each other in series. Furthermore, the connection of the P-type thermoelectric element layer and the N-type thermoelectric element layer may be made via an electrode layer formed of a metal material having high electrical conductivity or the like from the viewpoint of stability of the connection and thermoelectric performance.

### <Film Substrate>

As the substrate of the thermoelectric conversion module which is used in the present invention, a plastic film which neither lowers the electrical conductivity of the thermoelectric element layer nor affects the increase of the thermal conductivity is used. Above all, a polyimide film, a polyamide film, a polyether imide film, a polyaramid film, and a polyamide-imide film are preferred from the standpoint that they are excellent in flexibility, and even in the case where a thin film formed of a thermoelectric semiconductor composition as mentioned later is subjected to an annealing treatment, the performance of the thermoelectric element layer can be maintained without causing thermal deformation of the substrate, and the heat resistance and the dimensional stability are high; and furthermore, a polyimide film is especially preferred from the standpoint that it is high in versatility.

The thickness of the film substrate is preferably 1 to 1,000 μm, more preferably 10 to 500 μm, and still more preferably 20 to 100 μm from the viewpoint of flexibility, heat resistance, and dimensional stability.

As for the aforementioned film, its decomposition temperature is preferably 300° C. or higher.

### <Electrode Layer>

The electrode layer which is used in the present invention is provided for the purpose of electrically connecting a P-type thermoelectric element layer and an N-type thermoelectric element layer constituting the thermoelectric element layer with each other. Examples of an electrode material include gold, silver, nickel, copper, and an alloy thereof.

The thickness of the electrode layer is preferably 10 nm to 200 μm, more preferably 30 nm to 150 μm, and still more preferably 50 nm to 120 μm. When the thickness of the electrode layer falls within the aforementioned range, the electrical conductivity is high, and the resistance is low, so that a total electric resistance value of the thermoelectric element layer is controlled to a low level. In addition, a sufficient strength as the electrode is obtained.

### <Thermoelectric Element Layer>

Preferably, the thermoelectric element layer which is used in the present invention is a layer formed of a thermoelectric semiconductor composition containing thermoelectric semiconductor fine particles, a heat-resistant resin, and one or both of an ionic liquid and an inorganic ionic compound on the film substrate.

### (Thermoelectric Semiconductor Fine Particles)

As for the thermoelectric semiconductor fine particles which are used for the thermoelectric element layer, it is preferred that a thermoelectric semiconductor material is pulverized to a predetermined size by a pulverizer or the like.

A material constituting each of the P-type thermoelectric element layer and the N-type thermoelectric element layer, which is used in the present invention, is not particularly limited so long as it is a material capable of generating a thermoelectromotive force by giving a temperature difference. Examples thereof include bismuth-tellurium-based thermoelectric semiconductor materials, such as P-type bismuth telluride and N-type bismuth telluride; telluride-based thermoelectric semiconductor materials, such as GeTe and PbTe; antimony-tellurium-based thermoelectric semiconductor materials; zinc-antimony-based thermoelectric semiconductor materials, such as ZnSb, Zn₃Sb₂, and Zn₄Sb_{b 3}; silicon-germanium-based thermoelectric semiconductor materials, such as SiGe; bismuth-selenide-based thermoelectric semiconductor materials, such as Bi₂Se₃; silicide-based thermoelectric semiconductor materials, such as β-FeSi₂, CrSi₂, MnSi_{1.73}, and Mg₂Si; oxide-based thermoelectric semiconductor materials; whistler materials, such as FeVAl, FeVAISi, and FeVTiAl; and sulfide-based thermoelectric semiconductor materials, such as TiS₂.

Of these, a bismuth-tellurium-based thermoelectric semiconductor material, such as P-type bismuth telluride and N-type bismuth telluride, is preferred as the thermoelectric semiconductor material which is used in the present invention.

The P-type bismuth telluride is one in which the carrier is a hole, and the Seebeck coefficient is a positive value, and for example, one represented by Bi_{X}Te₃Sb_{2-X} is preferably used. In this case, X is preferably 0<X≤0.8, and more preferably 0.4≤X≤0.6. When X is more than 0 and 0.8 or less, the Seebeck coefficient and the electrical conductivity become large, and the characteristics as a P-type thermoelectric conversion material are maintained, and hence, such is preferred.

The N-type bismuth telluride is one in which the carrier is an electron, and the Seebeck coefficient is a negative value, and for example, one represented by Bi₂Te_{3-Y}Se_{Y} is preferably used. In this case, Y is preferably 0≤Y≤3 (when Y=0, Bi₂Te₃), and more preferably 0.1<Y≤2.7. When Y is 0 or more and 3 or less, the Seebeck coefficient and the electrical conductivity become large, and the characteristics as an N-type thermoelectric conversion material are maintained, and hence, such is preferred.

The blending amount of the thermoelectric semiconductor fine particles in the thermoelectric semiconductor composition is preferably 30 to 99% by mass, more preferably 50 to 96% by mass, and still more preferably 70 to 95% by mass. When the blending amount of the thermoelectric semiconductor fine particles falls within the aforementioned range, the Seebeck coefficient (an absolute value of the Peltier coefficient) is large, the lowering of the electrical conductivity is suppressed, and only the thermal conductivity is lowered, and therefore, a film not only exhibiting a high thermoelectric performance but also having sufficient film strength and flexibility is obtained. Thus, such is preferred.

The average particle diameter of the thermoelectric semiconductor fine particles is preferably 10 nm or 200 μm, more preferably 10 nm to 30 μm, still more preferably 50 nm to 10 μm, and especially preferably 1 to 6 μm. When the average particle diameter of the thermoelectric semiconductor fine particles falls within the aforementioned range, the uniform dispersion becomes easy, and the electrical conductivity can be enhanced.

A method of pulverizing the thermoelectric semiconductor material to obtain thermoelectric semiconductor fine particles is not particularly limited, and the thermoelectric semiconductor material may be pulverized to a predetermined size by a known pulverizer, such as a jet mill, a ball mill, a beads mill, a colloid mill, a conical mill, a disk mill, an edge mill, a grinding mill, a hammer mill, a pellet mill, a Willy mill, and a roller mill.

The average particle diameter of the thermoelectric semiconductor fine particles is one obtained through measurement with a laser diffraction particle size analyzer (1064 Model, manufactured by CILAS), and a median value of the particle size distribution was taken.

The thermoelectric semiconductor fine particles are preferably ones having been subjected to an annealing treatment (hereinafter sometimes referred to as “annealing treatment A”). As for the thermoelectric semiconductor fine particles, by performing the annealing treatment A, the crystallinity is improved, and furthermore, the surface oxide films of the thermoelectric semiconductor fine particles are removed, and therefore, the Seebeck coefficient (an absolute value of the Peltier coefficient) of the thermoelectric conversion material increases, whereby a figure of merit can be more improved. Though the annealing treatment Ais not particularly limited, the annealing treatment Ais preferably performed in an inert gas atmosphere of nitrogen, argon, or the like, in which the gas flow rate is controlled, or in a reducing gas atmosphere of hydrogen or the like, in which the gas flow rate is similarly controlled, or in a vacuum condition, such that the thermoelectric semiconductor fine particles are not adversely affected before preparation of the thermoelectric semiconductor composition. The annealing treatment A is more preferably performed in a mixed gas atmosphere of an inert gas and a reducing gas. Though a specific temperature condition depends upon the thermoelectric semiconductor fine particles to be used, typically, it is preferred to perform the annealing treatment A at a temperature of not higher than the melting point of the fine particles and at 100 to 1,500° C. for several minutes to several tens hours.

### (Heat-Resistant Resin)

The heat-resistant resin which is used in the present invention is one acting as a binder between the thermoelectric semiconductor fine particles and enhancing the flexibility of the thermoelectric conversion material. Though the heat-resistant resin is not particularly limited, a heat-resistant resin in which various physical properties as a resin, such as mechanical strength and thermal conductivity, are maintained without being impaired on the occasion of subjecting the thermoelectric semiconductor fine particles to crystal growth through an annealing treatment of a thin film formed of the thermoelectric semiconductor composition, or the like, is used.

Examples of the heat-resistant resin include a polyamide resin, a polyamide-imide resin, a polyimide resin, a polyether imide resin, a polybenzoxazole resin, a polybenzimidazole resin, an epoxy resin, and a copolymer having a chemical structure of such a resin. The heat-resistant resin may be used either alone or in combination of two or more thereof. Of these, a polyamide resin, a polyamide-imide resin, a polyimide resin, and an epoxy resin are preferred from the standpoint that not only the heat resistance is higher, but also the crystal growth of the thermoelectric semiconductor fine particles in the thin film is not adversely affected; and a polyamide resin, a polyamide-imide resin, and a polyimide resin are more preferred from the standpoint that the flexibility is excellent. In the case of using a polyimide film as the aforementioned support, a polyimide resin is more preferred as the heat-resistant resin from the standpoint of adhesion to the polyimide film. In the present invention, the polyimide resin is a generic term for a polyimide and a precursor thereof.

Preferably, the heat-resistant resin has a decomposition temperature of 300° C. or higher. When the decomposition temperature falls within the aforementioned range, even in the case of subjecting the thin film formed of the thermoelectric semiconductor composition to an annealing treatment as mentioned later, the flexibility of the thermoelectric conversion material can be maintained without losing the function as the binder.

As for the heat-resistant resin, its mass reduction rate at 300° C. by the thermogravimetry (TG) is preferably 10% or less, more preferably 5% or less, and still more preferably 1% or less. When the mass reduction rate falls within the aforementioned range, even in the case of subjecting the thin film formed of the thermoelectric semiconductor composition to an annealing treatment as mentioned later, the flexibility of the thermoelectric conversion material can be maintained without losing the function as the binder.

The blending amount of the heat-resistant resin in the thermoelectric semiconductor composition is preferably 0.1 to 40% by mass, more preferably 0.5 to 20% by mass, and still more preferably 1 to 20% by mass. When the blending amount of the heat-resistant resin falls within the aforementioned range, a film in which both high thermoelectric performance and film strength are compatible with each other is obtained.

### (Ionic Liquid)

The ionic liquid which is used in the present invention is a molten salt composed of a combination of a cation and an anion and refers to a salt capable of existing as a liquid in a broad temperature region of −50 to 500° C. The ionic liquid has such characteristic features that it has an extremely low vapor pressure and is nonvolatile; it has excellent heat stability and electrochemical stability; its viscosity is low; and its ionic conductivity is high, and therefore, the ionic liquid is able to effectively suppress a reduction of the electrical conductivity between the thermoelectric semiconductor fine particles as an electrical conductive assistant. In addition, the ionic liquid exhibits high polarity based on the aprotic ionic structure thereof and is excellent in compatibility with a heat-resistant resin, and therefore, the ionic liquid can make the thermoelectric conversion material have a uniform electrical conductivity.

As the ionic liquid, any known materials or commercially available products can be used. Examples thereof include those constituted of a cation component, such as a nitrogen-containing cyclic cation compound, e.g., pyridinium, pyrimidinium, pyrazolium, pyrrolidinium, piperidinium, and imidazolium, and a derivative thereof, a tetraalkylammonium type amine-based cation and a derivative thereof, a phosphine-based cation, e.g., phosphonium, a trialkylsulfonium, and a tetraalkylphosphonium, and a derivative thereof, and a lithium cation and a derivative thereof; and an anion component, such as Cl⁻, Br⁻, I⁻, AlCl₄⁻, Al₂Cl₇⁻, BF₄⁻, PF₆⁻, ClO₄⁻, NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N⁻, C₄F₉SO₃⁻, (C₂F₅SO₂)₂N⁻, C₃F₇COO⁻, and (CF₃SO₂)(CF₃CO)N⁻.

Among the aforementioned ionic liquids, it is preferred that the cation component of the ionic liquid contains at least one selected from a pyridinium cation and a derivative thereof, and an imidazolium cation and a derivative thereof, from the viewpoint of securing the high-temperature stability and the compatibility between the thermoelectric semiconductor fine particles and the resin as well as from the viewpoint of suppressing a reduction in the electrical conductivity between thermoelectric semiconductor fine particles, and so on.

Specific examples of the ionic liquid in which the cation component contains any of a pyridinium cation and a derivative thereof include 4-methyl-butylpyridinium chloride, 3-methyl-butylpyridinium chloride, 4-m ethyl-hexylpyridinium chloride, 3-methyl -hexylp yridinium chloride, 4-m ethyl-octylp yridinium chloride, 3-m ethyl-octylp yriclinium chloride, 3,4-dimethyl-butylpyridinium chloride, 3,5-dimethyl-butylpyridinium chloride, 4-methyl-butylpyridinium tetrafluorob orate , 4-methyl-butylpyridinium hexafluorophosphate, 1-butyl-4-methylpyridinium bromide, and 1-butyl-4-methylpyridinium hexafluorophosphate. Of these, 1-butyl-4-methylpyriclinium bromide and 1-butyl-4-methylpyridinium hexafluorophosphate are preferred.

Specific examples of the ionic liquid in which the cation component contains any of an imidazolium cation and a derivative thereof include [1-butyl-3-(2-hydroxyethyl)imidazolium bromide], [1-butyl-3-(2-hydroxyethyl)imidazolium tetrafluoroborate], 1-ethyl-3-methylimidazolium chloride, 1-ethyl -3-methylimidaz olium bromide, 1-butyl-3-methylimidazolium chloride, 1-hexyl-3-methylimidazolium chloride, 1-octyl-3-methylimidazolium chloride, 1-decyl-3-methylimidazolium chloride, 1-decyl-3-methylimidazolium bromide, 1-dodecyl-3-methylimidazolium chloride, 1-tetradecyl-3-methylimidazolium chloride, 1-ethyl-3-methylimidazolium tetrafluoroborate, 1-butyl-3-methylimidazolium tetrafluoroborate, 1-hexyl-3-m thylimidazolium tetrafluoroborate, 1-ethyl-3-methylimidazolium hexafluorophosphate, 1-butyl-3-m ethylimidazolium hexafluorophosphate, 1-methyl-3-butylimidazolium methyl sulfate, and 1,3-dibutylimidazolium methyl sulfate. Of these, [1-butyl-3-(2-hydroxyethypimidazolium bromide] and [1-butyl-3-(2-hydroxyethypimidazolium tetrafluoroborate] are preferred.

Preferably, the aforementioned ionic liquid has an electrical conductivity of 10⁻⁷ S/cm or more. When the ionic conductivity falls within the aforementioned range, a reduction of the electrical conductivity between the thermoelectric semiconductor fine particles can be effectively suppressed as the electrical conductive assistant.

Preferably, the ionic liquid has a decomposition temperature of 300° C. or higher. When the decomposition temperature falls within the aforementioned range, even in the case of subjecting the thin film formed of the thermoelectric semiconductor composition to an annealing treatment as mentioned later, the effect as the electrical conductive assistant can be maintained.

As for the ionic liquid, its mass reduction rate at 300° C. by the thermogravimetry (TG) is preferably 10% or less, more preferably 5% or less, and still more preferably 1% or less. When the mass reduction rate falls within the aforementioned range, even in the case of subjecting the thin film formed of the thermoelectric semiconductor composition to an annealing treatment as mentioned later, the effect as the electrical conductive assistant can be maintained.

The blending amount of the ionic liquid in the thermoelectric semiconductor composition is preferably 0.01 to 50% by mass, more preferably 0.5 to 30% by mass, and still more preferably 1.0 to 20% by mass. When the blending amount of the ionic liquid falls within the aforementioned range, a lowering of the electrical conductivity is effectively suppressed, and a film having a high thermoelectric performance is obtained.

### (Inorganic Ionic Compound)

The inorganic ionic compound which is used in the present invention is a compound constituted of at least a cation and an anion. The inorganic ionic compound exists as a solid in a broad temperature region of 400 to 900° C. and has such a characteristic feature that its ionic conductivity is high, and therefore, it is able to suppress a reduction of the electrical conductivity between the thermoelectric semiconductor fine particles as the electrical conductive assistant.

A metal cation is used as the cation.

Examples of the metal cation include an alkali metal cation, an alkaline earth metal cation, a typical metal cation, and a transition metal cation, with an alkali metal cation or an alkaline earth metal cation being preferred.

Examples of the alkali metal cation include Li⁺, Na⁺, K⁺, Rb⁺, Cs⁺, and Fr⁺.

Examples of the alkaline earth metal cation include Mg²⁺, Ca²⁺, Sr²⁺, and Ba²⁺.

Examples of the anion include F⁻, Cl⁻, Br⁻, I⁻, OH⁻, CN⁻, NO₃⁻, NO₂⁻, ClO⁻, ClO₂⁻, ClO₃⁻, ClO₄⁻, CrO₄²⁻, HSO₄⁻, SCN⁻, BF₄⁻, and PF₆⁻.

As the inorganic ionic compound, any known materials or commercially available products can be used. Examples thereof include those constituted of a cation component, such as a potassium cation, a sodium cation, and a lithium cation; and an anion component, such as a halide ion, for example, a chloride ion, e.g., Cl⁻, AlCl₄⁻, Al₂Cl₇⁻, and ClO₄⁻, a bromide ion, e.g., Br⁻, an iodide ion, such as I⁻, a fluoride ion, e.g., BF₄⁻ and PF₆⁻, and F(HF)ₙ⁻, NO₃⁻, OH⁻, and CN⁻.

Among the aforementioned inorganic ionic compounds, it is preferred that the cation component of the inorganic ionic compound contains at least one selected from potassium, sodium, and lithium from the viewpoint of securing the high-temperature stability and the compatibility between the thermoelectric semiconductor fine particles and the resin as well as from the viewpoint of suppressing a lowering of the electrical conductivity between thermoelectric semiconductor fine particles, and so on. In addition, the anion component of the inorganic ionic compound contains preferably a halide anion, and more preferably at least one selected from Cl⁻, Br⁻, and I⁻.

Specific examples of the inorganic ionic compound in which the cation component contains a potassium cation include KBr, KI, KCl, KF, KOH, and K₂CO₃. Of these, KBr and KI are preferred.

Specific examples of the inorganic ionic compound in which the cation component contains a sodium cation include NaBr, NaI, NaOH, NaF, and Na₂CO₃. Of these, NaBr and NaI are preferred.

Specific examples of the inorganic ionic compound in which the cation component contains a lithium cation include LiF, LiOH, and LiNO₃. Of these, LiF and LiOH are preferred.

The aforementioned inorganic ionic compound has an electrical conductivity of preferably 10⁻⁷ S/cm or more, and more preferably 10⁻⁶ S/cm or more. When the electrical conductivity falls within the aforementioned range, a reduction of the electrical conductivity between the thermoelectric semiconductor fine particles can be effectively suppressed as the electrical conductive assistant.

Preferably, the inorganic ionic compound has a decomposition temperature of 400° C. or higher. When the decomposition temperature falls within the aforementioned range, even in the case of subjecting the thin film formed of the thermoelectric semiconductor composition to an annealing treatment as mentioned later, the effect as the electrical conductive assistant can be maintained.

As for the inorganic ionic compound, its mass reduction rate at 400° C. by the thermogravimetry (TG) is preferably 10% or less, more preferably 5% or less, and still more preferably 1% or less. When the mass reduction rate falls within the aforementioned range, even in the case of subjecting the thin film formed of the thermoelectric semiconductor composition to an annealing treatment as mentioned later, the effect as the electrical conductive assistant can be maintained.

The blending amount of the inorganic ionic compound in the thermoelectric semiconductor composition is preferably 0.01 to 50% by mass, more preferably 0.5 to 30% by mass, and still more preferably 1.0 to 10% by mass. When the blending amount of the inorganic ionic compound falls within the aforementioned range, a lowering of the electrical conductivity can be effectively suppressed, and as a result, a film having an improved thermoelectric performance is obtained.

In the case of using a combination of the inorganic ionic compound and the ionic liquid, the total amount of contents of the inorganic ionic compound and the ionic liquid in the thermoelectric semiconductor composition is preferably 0.01 to 50% by mass, more preferably 0.5 to 30% by mass, and still more preferably 1.0 to 10% by mass.

The thickness of the thermoelectric element layer composed of the P-type thermoelectric element layer and the N-type thermoelectric element layer is not particularly limited, and it may be either identical or different (a difference in level is generated in a connecting portion). From the viewpoint of flexibility and material costs, the thickness of each of the P-type thermoelectric element layer and the N-type thermoelectric element layer is preferably 0.1 to 100 μm, and more preferably 1 to 50 μm.

### [Production Method of Thermoelectric Conversion Device Layer]

The production method of the thermoelectric conversion device layer of the present invention includes a step of forming the thermoelectric element layer on one face of the film substrate; and a step of forming the sealing layer on the face of the thermoelectric element layer.

The steps which are included in the present invention are hereunder successively described.

### <Thermoelectric Element Layer-Forming Step>

The thermoelectric element layer which is used in the present invention is formed of the aforementioned thermoelectric semiconductor composition on one face of the aforementioned film substrate. Examples of a method of applying the thermoelectric semiconductor composition on the film substrate include known methods, such as screen printing, flexographic printing, gravure printing, spin coating, dip coating, die coating, spray coating, bar coating, and doctor blade coating, without being particularly limited. In the case where the coating film is pattern-like formed, screen printing, slot the coating, or the like, capable of forming a pattern in a simplified manner using a screen plate having a desired pattern, is preferably adopted.

Subsequently, the resultant coating film is dried to give a thin film. As the drying method, any conventionally known drying method, such as hot air drying, hot roll drying, and IR radiation, is employable. The heating temperature is typically 80 to 150° C., and though the heating time varies depending upon the heating method, it is typically a few seconds to several tens minutes.

In the case where a solvent is used in preparing the thermoelectric semiconductor composition, the heating temperature is not particularly limited so long as it falls within a range of temperature at which the used solvent can be dried.

### <Sealing Layer-Forming Step>

The sealing layer-forming step is a step of forming the sealing layer on the face of the thermoelectric element layer. In addition, a step of forming the sealing layer on the other face of the film substrate not having the thermoelectric element layer is also included.

The formation of the sealing layer can be performed by a known method, and the sealing layer may be formed directly on the face of the thermoelectric element layer, or the sealing layer may be formed by sticking a sealing layer having been formed on a release sheet in advance onto the thermoelectric element layer and then transferring the sealing layer onto the thermoelectric element layer.

### <Sealing Base Material Layer-Forming Step>

Preferably, the production process of the thermoelectric conversion device layer further includes a sealing base material layer-forming step. The sealing base material layer-forming step is a step of forming the sealing base material layer on the face of the sealing layer.

The formation of the sealing base material layer can be performed by a known method, and the sealing base material layer may be formed directly on the face of the sealing layer, or the sealing base material layer may be formed by sticking a sealing base material layer having been formed on a release sheet in advance onto the sealing layer and then transferring the sealing base material layer onto the sealing layer.

### <Electrode-Forming Step>

Preferably, the production process of the thermoelectric conversion device layer further includes an electrode-forming step of forming an electrode layer on the film substrate by using the aforementioned electrode material and so on. Examples of a method of forming an electrode on the film substrate include a method in which after an electrode layer having no pattern formed thereon is provided on the substrate, the resultant is processed into a predetermined pattern shape by a known physical treatment or chemical treatment, mainly those in the photolithography method, or a combination thereof; and a method in which a pattern of an electrode layer is directly formed by a screen printing method, an inkjet method, or the like.

Examples of the forming method of an electrode layer having no pattern formed thereon include dry processes, such as PVD (physical vapor deposition method), e.g., a vacuum evaporation method, a sputtering method, and an ion plating method, and CVD (chemical vapor deposition method), e.g., hot CVD and atomic layer deposition (ALD); wet processes, such as various coating, e.g., a dip coating method, a spin coating method, a spray coating method, a gravure coating method, a die coating method, and a doctor blade method, or electrodeposition method or the like; a silver salt method, an electroplating method, an electroless plating method, and lamination of a metal foil, and the forming method is properly selected according to the material of the electrode layer.

In accordance with the production method of the present invention, a thermoelectric conversion device layer capable of suppressing interpenetration of the water vapor in the air into the thermoelectric element layer can be produced through a simple method.

### EXAMPLES

Next, the present invention is described in more detail by reference to Examples, but it should be construed that the present invention is by no means limited by these Examples.

The electric resistance of the thermoelectric conversion device layer prepared in each of the Examples and Comparative Examples, and the water vapor transmission rate of each of the sealing layer and the sealing base material layer were evaluated by the following methods.

### (a) Evaluation of Electric Resistance Value

An electric resistance value between output electrodes of the obtained thermoelectric conversion device layer was measured with DIGITAL HiTESTER (Model name: 3801-50, manufactured by Hioki E.E. Corporation) in the environment at 25° C. and 50% RH.

### (b) Water Vapor Transmission Rate (WVTR)

A water vapor transmission rate (g·m⁻²·day⁻¹) of the sealing layer was measured with a water vapor transmission rate analyzer (an apparatus name: L80-5000, manufactured by Systech Illinois) at 40° C. and 90% RH in conformity with JIS K7129. In addition, a water vapor transmission rate (g·m⁻²·day⁻¹) of the sealing base material layer was similarly measured with a water vapor transmission rate analyzer (an apparatus name: AQUATRAN, manufactured by MOCON, Inc.) at 40° C. and 90% RH in conformity with JIS K7129.

### <Preparation of Thermoelectric Element Layer>

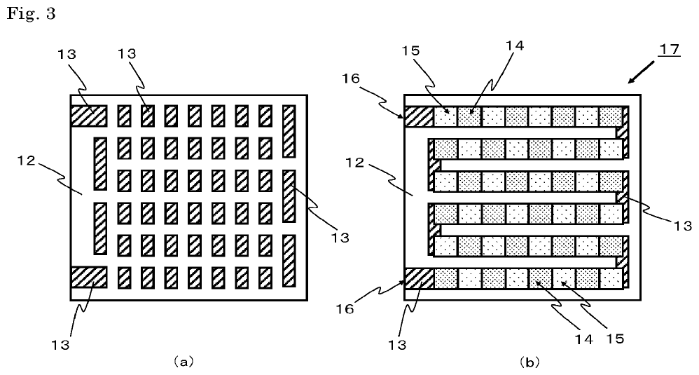

FIG. 3 is a plan view showing a configuration of the thermoelectric element layer used in the Examples, in which (a) shows a disposition of electrodes formed on a film substrate, and (b) shows a disposition of P-type and N-type thermoelectric elements formed on electrodes.

A nickel (9 μm) layer was formed on a copper foil of a copper foil-stuck polyimide film substrate (a product name; UPISEL N, manufactured by Ube Exsymo Co., Ltd., polyimide substrate thickness: 50 μm, copper foil: 9 μm) by means of electroless plating; subsequently, coating liquids (P) and (N) as mentioned later were applied onto an electrode 13 of a polyimide film substrate 12 provided with a pattern of the electrode 13 by forming a gold layer (thickness: 300 nm) on the nickel layer by means of electroless plating; and a P-type thermoelectric element 15 and an N-type thermoelectric element 14 were alternately disposed to be adjacent to each other, thereby preparing a thermoelectric conversion module 17 including a thermoelectric element layer 16 formed by providing 380 pairs of the P-type thermoelectric element and the N-type thermoelectric element each having a size of 1 mm×6 mm in series on the plane of the polyimide film substrate 12.

### (Preparation Method of Thermoelectric Semiconductor Fine Particles)

P-type bismuth telluride Bio ₄Te₃Sb_{1.6} (manufactured by Kojundo Chemical Laboratory Co., Ltd., particle diameter: 180 μm) that is a bismuth-tellurium-based thermoelectric semiconductor material was pulverized in a nitrogen gas atmosphere by using a planetary ball mill (Premium line P-7, manufactured by Fritsch Japan Co., Ltd.), thereby preparing thermoelectric semiconductor fine particles T1 having an average particle diameter of 1.2 μm. With respect to the thermoelectric semiconductor fine particles obtained through pulverization, the particle size distribution was measured with a laser diffraction particle size analyzer (MASTERSIZER 3000, manufactured by Malvern Panalytical Ltd.).

N-type bismuth telluride Bi₂Te₃ (manufactured by Kojundo Chemical Laboratory Co., Ltd., particle diameter: 180 μm) that is a bismuth-tellurium-based thermoelectric semiconductor material was pulverized in the same manner as mentioned above, thereby preparing thermoelectric semiconductor fine particles T2 having an average particle diameter of 1.4 μm.

### (Preparation of Thermoelectric Semiconductor Composition) Coating Liquid (P)

A coating liquid (P) composed of a thermoelectric semiconductor composition obtained by mixing and dispersing 90 parts by mass of the obtained fine particles T1 of a P-type bismuth-tellurium-based thermoelectric semiconductor material, 5 parts by mass of, as a heat-resistant resin, polyamic acid (a poly(pyromellitic dianhydride-co-4,4′-oxydianiline)amide acid solution, manufactured by Sigma-Aldrich, solvent: N-methylpyrrolidone, solid content concentration: 15% by mass) that is a polyimide precursor, and 5 parts by mass of, as an ionic liquid, [1-butyl-3-(2-hydroxyethyDimidazolium bromide] was prepared.

### Coating Liquid (N)

A coating liquid (N) composed of a thermoelectric semiconductor composition obtained by mixing and dispersing 90 parts by mass of the obtained fine particles T2 of an N-type bismuth-tellurium-based thermoelectric semiconductor material, 5 parts by mass of, as a heat-resistant resin, polyamic acid (a poly(pyromellitic dianhydride-co-4,4′-oxydianiline)amide acid solution, manufactured by Sigma-Aldrich, solvent: N-methylpyrrolidone, solid content concentration: 15% by mass) that is a polyimide precursor, and 5 parts by mass of, as an ionic liquid, [1-butyl-3-(2-hydroxyethypimidazolium bromide] was prepared.

### (Formation of Thermoelectric Element Layer)

The above-prepared coating liquid (P) was applied on the aforementioned polyimide film by the screen printing method and then dried in an argon atmosphere at a temperature of 150° C. for 10 minutes, thereby forming a thin film having a thickness of 50 _{J}im. Subsequently, the above-prepared coating liquid (N) was similarly applied on the aforementioned polyimide film and then dried in an argon atmosphere at a temperature of 150° C. for 10 minutes, thereby forming a thin film having a thickness of 50 μm.

Furthermore, each of the obtained thin films was subjected to temperature elevation in a mixed gas atmosphere of hydrogen and argon (hydrogen/argon=3% by mass/97% by mass) at a temperature rise rate of 5 K/min and then held at 325° C. for 30 minutes, and an annealing treatment after the thin film formation was performed to undergo crystal growth of the fine particles of the thermoelectric semiconductor material. There was thus prepared a thermoelectric element layer composed of the P-type thermoelectric element layer and the N-type thermoelectric element layer.

### Example 1

### <Preparation of Thermoelectric Conversion Device Layer>

A polyolefin-based resin (thickness: 25 μm, WVTR: 6.0 g·m⁻²·day⁻¹) was stuck directly as a sealing layer onto the face of the thermoelectric element layer which had been prepared on one face of the polyimide film substrate, thereby preparing a thermoelectric conversion device layer.

As for the formation method of a sealing layer, first of all, the polyolefin-based resin was formed on a release film by an already-known coating method. Thereafter, the resultant was stuck onto the thermoelectric element layer by using a laminator, and then, the release film was released to form a sealing layer.

As for the polyolefin-based resin, 5 parts by mass of a polyisoprene-based rubber having a carboxylic acid-based functional group (LIR410, manufactured by Kuraray Co., Ltd., number average molecular weight: 30,000, number of carboxylic acid-based functional group per molecule: 10), 100 parts by mass of a rubber-based polymer not having a carboxylic acid-based functional group: a copolymer of isobutylene and isoprene (Exxon Butyl 268, manufactured by Japan Butyl Co., Ltd., number average molecular weight: 260,000), and 2 parts by mass of an epoxy compound (TC-5, manufactured by Mitsubishi Chemical Corporation) were dissolved in toluene, thereby preparing a polyolefin-based resin having a solid content concentration of 25%.

### Example 2

The sealing layer used in Example 1 was further stuck onto the other face of the polyimide film substrate, on which the thermoelectric element layer was not provided, and a thermoelectric conversion device layer was prepared in the same manner as in Example 1.

### Example 3

A thermoelectric conversion device layer was prepared in the same manner as in Example 2, except that both of the sealing layers provided on the both faces of the polyimide film substrate of Example 2 were changed to an epoxy-based resin (thickness: 24 μm, WVTR: 160 g·m⁻²·day⁻¹); and that after sticking the sealing layers, the sealing layers were cured under a condition at 100° C. for 2 hours.

100 parts by mass of an acid-modified polyolefin-based resin (an α-olefin polymer, a trade name: UNISTOLE H-200, manufactured by Mitsui Chemicals, Inc., number average molecular weight: 47,000), 100 parts by mass of a polyfunctional epoxy compound (1) (hydrogenated bisphenol A diglycidyl ether, a trade name: EPOLIGHT 4000, manufactured by Kyoeisha Chemical Co., Ltd., epoxy equivalent: 215 to 245 g/eq, molecular weight: 800), 50 parts by mass of a tackifier (a styrene-based monomer aliphatic monomer copolymer, a trade name: FTR6100, manufactured by Mitsui Chemicals, Inc., softening point: 95° C.), and 1 part by mass of an imidazole-based curing catalyst (a trade name: CUREZOL 2E4MZ, manufactured by Shikoku Chemical Corporation, 2-ethyl-4-methylimidazole) were dissolved in methyl ethyl ketone, thereby preparing an epoxy-based resin having a solid content concentration of 30% by mass.

### Example 4

A thermoelectric conversion device layer was prepared in the same manner as in Example 2, except that both of the sealing layers provided on the both faces of the polyimide film substrate of Example 2 were changed to an acrylic resin (thickness: 22 μm, WVTR: 660 g·m⁻²·day⁻¹).

As for the acrylic resin, 100 parts by mass (solid content ratio) of an acrylic copolymer (n-butyl acrylate (BA)/acrylic acid (AA)=98.0/2.0 (mass ratio), weight average molecular weight: 1,000,000, solvent: ethyl acetate, solid content concentration: 15% by mass) was blended and mixed with 50 parts by mass (solid content ratio) of a rosin-base resin (a trade name: HARIESTER TF, manufactured by Harima Chemicals, Inc., softening point: 75 to 85° C.) as a tackifier and 1.5 parts by mass (solid content ratio) of an isocyanate-based crosslinking agent (a trade name: CORONATE L, manufactured by Tosoh Corporation, solid content concentration: 75% by mass) as a crosslinking agent, and the mixture was uniformly stirred to prepare an ethyl acetate solution of a pressure sensitive adhesive resin.

### Example 5

On each of the sealing layers provided on the both faces of the polyimide film substrate of Example 2, a sealing base material layer METALUMY S [manufactured by Toray Advanced Co., Ltd., aluminum deposited film (thickness: 50 nm)/PET (thickness: 25 μm), WVTR: 3.1 g·m⁻²·day⁻¹)] was further stuck such that the face of PET (the face not having the aluminum deposited film) was opposed to the sealing layer, and a thermoelectric conversion device layer was prepared in the same manner as in Example 2.

### Example 6

On each of the sealing layers provided on the both faces of the polyimide film substrate of Example 2, a transparent gas barrier film [a transparent gas barrier layer used in Example 1 of Japanese Patent Application No. 2015-218292, perhydropolysilazane layer (thickness: 150 nm)/PET (thickness: 25 μm), WVTR: 0.005 g·m⁻²·day⁻¹)] was further stuck such that the face of PET (the face not having the perhydropolysilazane layer) was opposed to the sealing layer, and a thermoelectric conversion device layer was prepared in the same manner as in Example 2.

### Comparative Example 1

A thermoelectric conversion device layer was prepared in the same manner as in Example 1, except for not sticking the sealing layer.

### Comparative Example 2

A thermoelectric conversion device layer was prepared in the same manner as in Example 2, except that both of the sealing layers provided on the both faces of the polyimide film substrate of Example 2 were changed to an acrylic pressure sensitive adhesive (thickness: 25 μm, WVTR: 1,700 g·m⁻²·day⁻¹).

As for the acrylic pressure sensitive adhesive, 77 parts by mass of n-butyl acrylate, 20 parts by mass of methyl acrylate, 3 parts of acrylic acid, and 0.3 parts by azobisisobutyronitrile as an initiator were added in 200 parts by mass of ethyl acetate and stirred at 65° C. for 17 hours, thereby obtaining an acrylic acid ester copolymer solution having a mass average molecular weight of 800,000. To 100 parts by mass of the obtained copolymer, 2.0 parts by mass of a crosslinking agent composed of a tolylene diisocyanate-based polyisocyanate compound (a trade name: CORONATE L, manufactured by Nippon Polyurethane Industry Co., Ltd.), 0.5 parts by mass of a crosslinking agent composed of an aluminum chelate compound (a trade name: ALCH-TR, manufactured by Kawaken Chemicals Co., Ltd.), and 0.5 parts by mass of a silane coupling agent (a trade name: KBM-403, manufactured by Shin-Etsu Chemical Co., Ltd.) were added, followed by diluting with toluene, thereby preparing a solution of about 20% by mass.

The thermoelectric conversion device layer obtained in each of Examples 1 to 6 and Comparative Examples 1 and 2 was subjected to a durability test of storing in an environment at 60° C. and 90% RH for 1,000 hours, and the electric resistance value between the output electrodes of the thermoelectric conversion device layer before and after the test was measured. The measurement results are shown in Table 1 along with the water vapor transmission rates of the used sealing layer and sealing base material layer.

TABLE 1

| | | | | Sealing | | Resistance (Ω) | | Resistance |
|---|---|---|---|---|---|---|---|---|
| | | WVTR | | base | WVTR | Before | After | increase |
| | Sealing | (g · m⁻² · | Sticking | material | (g · m⁻² · | durability | durability | rate |
| | layer | day⁻¹) | site | layer | day⁻¹) | test | test | (%) |
| Example 1 | Polyolefin- | 6 | One | — | — | 400 | 700 | 75 |
| | based resin | | face | | | | | |
| Example 2 | Polyolefin- | 6 | Both | — | — | 390 | 520 | 33 |
| | based resin | | faces | | | | | |
| Example 3 | Epoxy- | 160 | Both | — | — | 400 | 730 | 83 |
| | based | | faces | | | | | |
| | resin | | | | | | | |
| Example 4 | Acrylic | 660 | Both | — | — | 310 | 710 | 130 |
| | resin | | faces | | | | | |
| Example 5 | Polyolefin- | 6 | Both | METALUMY S | 3.1 | 350 | 380 | 9 |
| | based resin | | faces | | | | | |
| Example 6 | Polyolefin- | 6 | Both | Transparent gas | 0.005 | 380 | 390 | 3 |
| | based resin | | faces | barrier film | | | | |
| Comparative | — | — | — | — | — | 360 | 77000 | 21300 |
| Example 1 | | | | | | | | |
| Comparative | Acrylic | 1700 | Both | | | 390 | 1060 | 170 |
| Example 2 | resin | | faces | | | | | |

In Example 1 in which the sealing layer is stuck on the face of the thermoelectric element layer of the thermoelectric conversion module, it is noted that the resistance increase rate after the durability test is much smaller, as compared with Comparative Example 1 in which the sealing layer is not stuck. In addition, in Example 2 in which the sealing layer is stuck on the both faces of the thermoelectric conversion module, it is noted that the resistance increase rate after the durability test is even smaller, as compared with Example 1. In Examples 5 and 6 in which the sealing base material layer is further stuck, it is noted that the resistance increase rate after the durability test is more sufficiently suppressed. From the foregoing results, in the thermoelectric conversion device layer of the present invention, it is expected that the thermoelectric performance is maintained over a long period of time even under a high-temperature and high-humidity condition.

### INDUSTRIAL APPLICABILITY

In view of the fact that the thermoelectric conversion device layer of the present invention has excellent durability, it is expected that the thermoelectric performance is maintained over a long period of time. For this reason, the thermoelectric conversion device layer of the present invention can be suitably used when installed in the environment of a waste heat source or heat dissipation source, or in the high-temperature and high-humidity environment.

### REFERENCE SIGNS LIST

1A, 1B: Thermoelectric conversion device layer

2: Film substrate

3: Electrode

4: N-type thermoelectric element

5: P-type thermoelectric element

6: Thermoelectric element layer

7: Thermoelectric conversion module

8: Sealing layer

9: Sealing base material layer

12: Polyimide film substrate

13: Copper electrode

14: N-type thermoelectric element

15: P-type thermoelectric element

16: Thermoelectric element layer

17: Thermoelectric conversion module

1. A thermoelectric conversion device layer comprising:
a thermoelectric conversion module comprising,
a film substrate, and
a thermoelectric element layer, on one face of the film substrate, in which a P-type thermoelectric element layer and an N-type thermoelectric element layer are alternately arranged to be adjacent to each other in an in-plane direction and disposed in series; and
a sealing layer on a face side of the thermoelectric element layer,
wherein the sealing layer has a water vapor transmission rate at 40° C. and 90% RH, as prescribed in JIS K7129:2008, of 1,000 g·m⁻²·day⁻¹ or less.

2. The thermoelectric conversion device layer according to claim 1, further comprising, on a face of the sealing layer:
a sealing base material layer having a water vapor transmission rate at 40° C. and 90% RH, as prescribed in JIS K7129:2008, of 10 g·m⁻²·day⁻¹ or less.

3. The thermoelectric conversion device layer according to claim 1, further comprising, on other face of the film substrate:
an additional sealing layer, or
an additional sealing layer and a sealing base material layer in this order.

4. The thermoelectric conversion device layer according to claim 1, wherein a main component constituting the sealing layer is a polyolefin-based resin, a curable resin, or an acrylic resin.

5. The thermoelectric conversion device layer according to claim 1, wherein the sealing layer has a thickness of 0.5 to 100 μm.

6. The thermoelectric conversion device layer according to claim 2, wherein the sealing base material layer is an inorganic layer or a layer containing a polymer compound.

7. The thermoelectric conversion device layer according to claim 2, wherein the sealing base material layer has a thickness of 10 to 100 μm.

8. The thermoelectric conversion device layer according to claim 1, wherein the thermoelectric element layer and the sealing layer come into direct contact with each other.

9. The thermoelectric conversion device layer according to claim 1, wherein the sealing layer is composed of a sealant having pressure sensitive adhesiveness.

10. A method of producing a thermoelectric conversion device layer which is the thermoelectric conversion device layer according to claim 1, the method comprising:
forming the thermoelectric element layer on one face of the film substrate; and
forming the sealing layer on the face of the thermoelectric element layer.

11. A thermoelectric conversion device layer, comprising:
a thermoelectric conversion module comprising,
a film substrate, and
a thermoelectric element layer, on one face of the film substrate, in which a P-type thermoelectric element layer and an N-type thermoelectric element layer are alternately arranged to be adjacent to each other in the in-plane direction and disposed in series; and
a sealing layer on the face side of the thermoelectric element layer,
wherein the sealing layer is composed of a curable resin.

12. The thermoelectric conversion device layer according to claim 2, further comprising, on other face of the film substrate:
an additional sealing layer, or
an additional sealing layer and an additional sealing base material layer in this order.
